(19) United States
(12) Patent Application Publication
(10) Pub. No.: US 2023/0096210 A1
(43) Pub. Date: Mar. 30, 2023

(54) ARRAY SUBSTRATE, METHOD OF MANUFACTURING THE SAME, AND DISPLAY PANEL

(71) Applicant: HKC CORPORATION LIMITED, Shenzhen (CN)

(72) Inventors: IL NAM SONG, Shenzhen (CN); WOOSUK HA, Shenzhen (CN); Haijiang YUAN, Shenzhen (CN)

(21) Appl. No.: 17/955,575

(22) Filed: Sep. 29, 2022

(30) Foreign Application Priority Data
Sep. 30, 2021 (CN) 202111165727.1

(51) Int. Cl. H01L 27/32; H01L 27/12

(52) U.S. Cl. CPC H01L 27/3272; H01L 27/1288

(57) ABSTRACT

An array substrate, a method of manufacturing the same, and a display panel are disclosed. The method includes: providing a substrate; depositing a light-shielding material on the substrate; and etching the light-shielding material to form a light-shielding layer, where an included angle formed between a side surface of the formed light-shielding layer and a plane where the substrate is located lies in the range of 80 to 110 degrees.

### CROSS-REFERENCE TO RELATED APPLICATIONS

This application claims the priority and benefit of Chinese patent application CN2021111657271, entitled “Array Substrate, Method of Manufacturing the Same, and Display Panel” and filed Sep. 30, 2021 with China National Intellectual Property Administration, the entire contents of which are incorporated herein by reference.

### TECHNICAL FIELD

This application relates to the field of display technology, and more particularly relates to an array substrate, a method of manufacturing the array substrate, and a display panel.

### BACKGROUND

The description provided in this section is intended for the mere purpose of providing background information related to the present application but doesn't necessarily constitute prior art.

OLED (Organic Light-Emitting Diode) is also known as organic electric laser display, or organic light-emitting semiconductor (Organic Electroluminescence Display, OLED). OLED has advantages of low power consumption, fast response speed, wide viewing angle, etc., and has been widely used. In the OLED panel, the light-shielding layer structure is an indispensable structure, which is arranged corresponding to the thin film transistor to prevent the current leakage problem of the semiconductor layer. In the OLED with Bottom Emission structure, in this type of display panel, the light emitted by the light-emitting layer is emitted from the side of the glass substrate through the planarization layer and the array substrate. Since the sides of the existing light-shielding layer structure are inclined, when the light emitted by the light-emitting structure penetrates the array substrate, a part of the light will hit the inclined side surface of the light-shielding layer structure to be reflected back into the panel, so that it cannot be emitted from the side of the glass substrate, resulting in the problem of low light transmittance of the display panel.

### SUMMARY

The present application provides an array substrate, a method of manufacturing the array substrate, and a display panel, aiming at solving the problem of low light transmittance efficiency of the existing array substrate.

The present application discloses a method of manufacturing an array substrate, including the following operations:

providing a substrate;

depositing a light-shielding material on the substrate; and

etching the light-shielding material to form a light-shielding layer, where an included angle between a side surface of the formed light-shielding layer and a plane where the substrate is located lies in the range of 80 to 110 degrees.

Optionally, the operation of depositing the light-shielding material on the substrate includes:

depositing a molybdenum alloy material or a titanium alloy material or a molybdenum titanium alloy material on the substrate to form a first light-shielding material with a thickness of 500 to 1500 angstroms; and

depositing a copper material or a copper oxide material or a chromium material or a chromium oxide material or an aluminum alloy material or an aluminum oxide material on the first light-shielding material to form a second light-shielding material with a thickness of 3500 to 6500 angstroms.

Optionally, the operation of etching the light-shielding material to form a light-shielding layer where an included angle between a side surface of the formed light-shielding layer and a plane where the substrate is located lies in the range of 80 to 110 degrees includes:

forming a photoresist on the second light-shielding material by means of yellow light exposure;

dry-etching the second light-shielding material to form a second light-shielding film layer:

wet-etching the first light-shielding material to form a second light-shielding film layer, where the included angle between the side surface of the light-shielding layer and the plane where the substrate is located lies in the range of 80 to 110 degrees; and

removing the photoresist.

Optionally, the operation of etching the light-shielding material to form a light-shielding layer where an included angle between the side surface of the formed light-shielding layer and a plane where the substrate is located lies in the range of 80 to 110 degrees includes:

forming a photoresist on the second light-shielding material through a halftone mask, the formed photoresist including a first photoresist portion and a second photoresist portion that are connected to each other, and the second photoresist portion is arranged in a circle around the periphery of the first photoresist portion, where the thickness of the first photoresist portion is greater than the thickness of the second photoresist portion;

dry-etching the second light-shielding material to form a second light-shielding preparatory film layer with a width corresponding to the total width of the first photoresist portion and the second photoresist portion, and further completely etching the second photoresist portion;

wet-etching the first light-shielding material to form a first light-shielding film layer with a width corresponding to the first photoresist portion, and at the same time, wet-etching the side surface of the second light-shielding preparatory film layer to obtain a second light-shielding film layer with a width corresponding to the first photoresist portion, where the included angle between the side surface of the light-shielding layer and the plane where the substrate is located lies in the range of 80 to 110 degrees; and

removing the photoresist.

Optionally, the operation of depositing the light-shielding material on the substrate includes:

depositing a molybdenum alloy material or a titanium alloy material or a molybdenum-titanium alloy material on the substrate to form a first light-shielding material with a thickness of 500 to 1500 angstroms:

depositing a copper material or a copper oxide material or a chromium material or a chromium oxide material or an aluminum alloy material or an aluminum oxide material on the first light-shielding material to form a second light-shielding material having a thickness of 3500 to 6500 angstroms; and

depositing a molybdenum alloy material, a titanium alloy material, or a molybdenum-titanium alloy material on the second light-shielding material to form a third light-shielding material with a thickness of 500 to 1500 angstroms.

Optionally, the operation of etching the light-shielding material to form a light-shielding layer, where the angle between the side surface of the formed light-shielding layer and the plane where the substrate is located is 80 to 110 degrees includes:

forming a photoresist on the third light-shielding material by means of yellow light exposure;

dry-etching the third light-shielding material to form a third light-shielding film layer;

wet-etching the second light-shielding material to form a second light-shielding film layer;

wet-etching the first light-shielding material to form a second light-shielding film layer, where the included angle between the side surface of the light-shielding layer and the plane where the substrate is located lies in the range of 80 to 110 degrees; and

removing the photoresist.

Optionally, the operation of etching the light-shielding material to form a light-shielding layer, where the angle between the side surface of the formed light-shielding layer and the plane where the substrate is located is 80 to 110 degrees includes:

forming a photoresist through a halftone mask on the third light-shielding material, the formed photoresist includes a first photoresist portion, a second photoresist portion and a third photoresist portion that are connected to each other, where the second photoresist portion is arranged in a circle around the periphery of the first photoresist portion, the third photoresist portion is arranged in a circle around the periphery of the second photoresist portion, where the thicknesses of the first photoresist portion, the second photoresist portion and the third photoresist portion are sequentially reduced;

dry etching the third light-shielding material to form a third light-shielding preparatory film layer with a width corresponding to the total width of the first photoresist portion, the second photoresist portion and the third photoresist portion, and at the same time, completely etching the third photoresist portion:

wet-etching the second light-shielding material to form a second light-shielding layer preparatory film with a width corresponding to the total width of the first photoresist portion and the second photoresist portion, and at the same time, wet-etching the side surface of the third light-shielding preparatory film layer to obtain a third light-shielding preparatory film layer with a width corresponding to the total width of the first photoresist portion and the second photoresist portion, and at the same time, fully etching the second photoresist portion:

wet-etching the first light-shielding material to form a second light-shielding film layer with a width corresponding to the width of the first photoresist portion, and at the same time, wet-etching the side surfaces of the second light-shielding preparatory film layer and the third light-shielding preparatory film layer to obtain a second light-shielding film layer and a third light-shielding film with a width corresponding to the width of the first photoresist portion layer, where the angle between the side surface of the light-shielding layer and the plane where the substrate is located is 80 to 110 degrees; and

removing the photoresist.

The present application further discloses an array substrate, including a substrate, a light-shielding layer, and a thin film transistor layer, where the light-shielding layer is disposed on the substrate, and the thin film transistor layer is disposed on the light-shielding layer. The angle between the side surface of the light-shielding layer and the plane where the substrate is located is 80 degrees to 110 degrees.

Optionally, the light-shielding layer includes a first light-shielding film layer and a second light-shielding film layer. The first light-shielding film layer is formed on the substrate, and the second light-shielding film layer is formed on the first light-shielding film layer.

Or the light-shielding layer includes a first light-shielding film layer, a second light-shielding film layer and a third light-shielding film layer. The first light-shielding film layer is formed on the substrate, the second light-shielding film layer is formed on the first light-shielding film layer, and the third light-shielding film layer is formed on the second light-shielding film layer.

The present application further discloses a display panel, including a light-emitting structure, an encapsulation layer, and the above-mentioned array substrate. The array substrate includes a color filter layer and a planarization layer. The thin film transistor layer includes a thin film transistor. The color filter layer is disposed on the side of the thin film transistor. The planarization layer is disposed on the light-shielding layer and the thin film transistor layer. The light emitting structure is formed on the planarization layer. The encapsulation layer is disposed on the light emitting structure.

Compared with the case where the side surface of the light-shielding layer structure is an inclined side surface, the array substrate of the present application has a relatively vertical structure because the angle between the side surface of the light-shielding layer and the plane where the substrate is located is 80 to 110 degrees. The light emitted by the panel will not be reflected back into the substrate by the side of the light-shielding layer, which is beneficial to improve the transmittance of light, improve the brightness of the display panel, and reduce power consumption. At the same time, it can prevent the light reflected back into the substrate from hitting the semiconductor layer of the thin film transistor and other positions, which will adversely affect the properties of the element. The array substrate of the present application is especially suitable for an OLED display panel adopting a Bottom Emission structure. In this type of display panel, the light emitted by the light-emitting structure will pass through the light-shielding layer and be emitted from one side of the substrate. In this case, the side of the light-shielding layer is vertical, which can increase the light transmittance more effectively.

### BRIEF DESCRIPTION OF DRAWINGS

The accompanying drawings, which are included to provide a further understanding of the embodiments of the present application, constitute a part of the specification, are used to illustrate the embodiments of the present application, and together with the written description, serve to explain the principles of the present application. Obviously, the drawings used in the following description merely depict some embodiments of the present application, and for those having ordinary skill in the art, other drawings can also be obtained from these drawings without investing creative effort. In the drawings:

FIG. 1 is a flowchart of a first embodiment of a method of manufacturing an array substrate of the present application.

FIG. 2 is a flowchart of a second embodiment of a method of manufacturing an array substrate of the present application.

FIG. 3 is a flowchart of a third embodiment of a method of manufacturing an array substrate of the present application.

FIG. 4 is a flowchart of a fourth embodiment of a method of manufacturing an array substrate of the present application.

FIG. 5 is a flowchart of a fifth embodiment of a method of manufacturing an array substrate of the present application.

FIG. 6 is a schematic diagram of an array substrate according to an embodiment of the present application.

FIG. 7 is a partial enlarged view of area A shown in FIG. 6 of the present application.

FIG. 8 is a schematic diagram of a light-shielding layer of a single-layer film structure according to an embodiment of the present disclosure.

FIG. 9a is a schematic diagram of a light-shielding layer of a double-layer film structure according to an embodiment of the present disclosure.

FIG. 9b is a schematic diagram of a light-shielding layer of a double-layer film structure according to another embodiment of the present disclosure.

FIG. 10a is a schematic diagram of a light-shielding layer of a three-layer film structure according to an embodiment of the present disclosure.

FIG. 10b is a schematic diagram of a light-shielding layer of a three-layer film structure according to another embodiment of the present disclosure.

### DETAILED DESCRIPTION OF EMBODIMENTS

It should be understood that the terminology used herein, the specific structural and functional details disclosed are intended for the mere purpose of describing specific embodiments and are representative, but the present application may be embodied in many alternative forms and should not be construed as limited only the embodiments set forth herein.

In the description of this application, the terms “first” and “second” are merely used for description purposes, and cannot be understood as indicating relative importance, or implicitly indicating the number of indicated technical features. Thus, unless otherwise specified, features defined as “first” and “second” may expressly or implicitly include one or more of the features; “plurality” means two or more. The terms “including”, “comprising”, and any variations thereof are intended to mean a non-exclusive inclusion, namely one or more other features, integers, steps, operations, units, components and/or combinations thereof may be present or added.

In addition, terms such as “center”, “transverse”, “lateral”, “above”. “on”, “under”, “below”, “left”, “right”, “vertical”, “horizontal”, “top”, “bottom”, “inside”, “outside”, etc., indicative of orientations or positional relationships are described based on the orientations or relative positional relationships illustrated in the drawings, and are intended for the mere purpose of convenience of simplified description of the present application, rather than indicating that the device or element referred to must have a specific orientation or be constructed, and operate in a particular orientation. Thus, these terms should not be construed as limiting the present application.

In addition, unless otherwise expressly specified and defined, terms “installed on”, “connected to”, and “coupled to” should be understood in a broad sense. For example, it may be a fixed connection, a detachable connection, or an integral connection; it may be a mechanical connection, or may also be an electrical connection; it may be a direct connection, an indirect connection through an intermediate medium, or an internal connection between two components. For those having ordinary skill in the art, the specific meanings of the above terms in this application can be understood depending on specific contexts.

The present application will be described in detail below with reference to the accompanying drawings and optional embodiments. It should be noted that, should no conflict be present, the embodiments or technical features described below can be arbitrarily combined to form new embodiments.

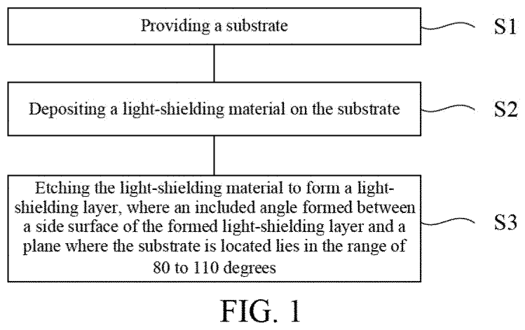

FIG. 1 is a flowchart of a first embodiment of a method of manufacturing an array substrate of the present application. As shown in FIG. 1, the present application discloses a method for manufacturing an array substrate, which includes the following steps:

S1: providing a substrate;

S2: depositing a light-shielding material on the substrate; and

S3: etching the light-shielding material to form a light-shielding layer 20, and the angle between the side surface of the formed light-shielding layer and the plane where the substrate is located is 80 to 110 degrees. (Typically, the angle between the side surface of the light-shielding layer 20 and the plane where the substrate is located is 85 degrees to 95 degrees.)

Compared with the case where the side surface of the light-shielding layer 20 structure is an inclined side surface, the array substrate of the present application has a relatively vertical structure because the angle between the side surface of the light-shielding layer 20 and the plane where the substrate is located is 80 to 110 degrees. The light emitted by the panel will not be reflected back into the substrate by the side of the light-shielding layer 20, which is beneficial to improve the transmittance of light, improve the brightness of the display panel, and reduce power consumption. At the same time, it can prevent the light reflected back into the substrate from hitting the semiconductor layer of the thin film transistor 301 and other positions, which will adversely affect the properties of the element.

It should be noted that, if the light-shielding layer 20 is disposed corresponding to the thin film transistor 301, the external light can also be blocked, so as to prevent the external light from affecting the thin film transistor layer 30 and causing deterioration of its characteristics.

The array substrate of the present application is especially suitable for an OLED display panel adopting a Bottom Emission structure. In this type of display panel, the light emitted by the light emitting structure will pass through the light-shielding layer 20 and be emitted from the side of the substrate. In this case, the side of the light-shielding layer 20 is vertical, which can increase the light transmittance more intuitively. At this time, the step of etching the light-shielding material to form a light-shielding layer 20, where the included angle between the side surface of the light-shielding layer 20 and the plane where the substrate is located is 80 to 110 degrees, further includes: forming a light-emitting structure with an active light-emitting layer above the light-shielding layer 20; the light-emitting structure emits light from the substrate side of the array substrate, the light-emitting structure may be directly fabricated on the array substrate, or may be fabricated on another substrate, which is then aligned and bonded together with the array substrate to form a cell.

In addition, film layers such as thin film transistors 301 are also formed above the light-shielding layer structure. At this time, the step of etching the light-shielding material to form a light-shielding layer 20, where the included angle between the side surface of the light-shielding layer 20 and the plane where the substrate is located is 80 to 110 degrees, further includes the step of: forming a thin film transistor 301 on the light-shielding layer 20, and forming a light-emitting structure with an active light-emitting layer on the thin-film transistor layer; where the “on” here means “in close contact with” the lower film layer, or above the lower film where they are spaced apart from each other, and the array substrate is also formed thereon with film layers such as a color filter layer and an encapsulation layer, as well as wires such as data lines and scan lines, etc., where this part however is not the focus of this application, and will not be detailed herein.

The light-shielding layer 20 can be a single-layer film layer, a double-layer film layer or a three-layer film layer structure. Taking a single-layer film layer as an example, it can be made of a molybdenum alloy material, a titanium alloy material, or a molybdenum-titanium alloy material, the thickness of the film layer is 300-7000 angstroms, which is thicker than the light-shielding layer 20 structure in the related art. The increase of the thickness can reduce the proportion of the upper edge of the film layer, where the tilt problem mainly occurs, to the side surface of the light-shielding layer 20. In the position other than the upper edge of the side, the etching environment is relatively consistent, which is conducive to forming the vertical side. In addition, the specific etching method can be dry etching or wet etching. Alternatively, dry etching can be used first to etch a part, and then wet etching can be used. By doing so, the upper edge of the film layer, which is more prone to over-etching, can be improved, so that the sides of the light-shielding layer 20 that is finally formed by etching are more vertical.

In particular, FIG. 8 shows a light-shielding layer 20 of a single-layer structure according to one embodiment of the present disclosure.

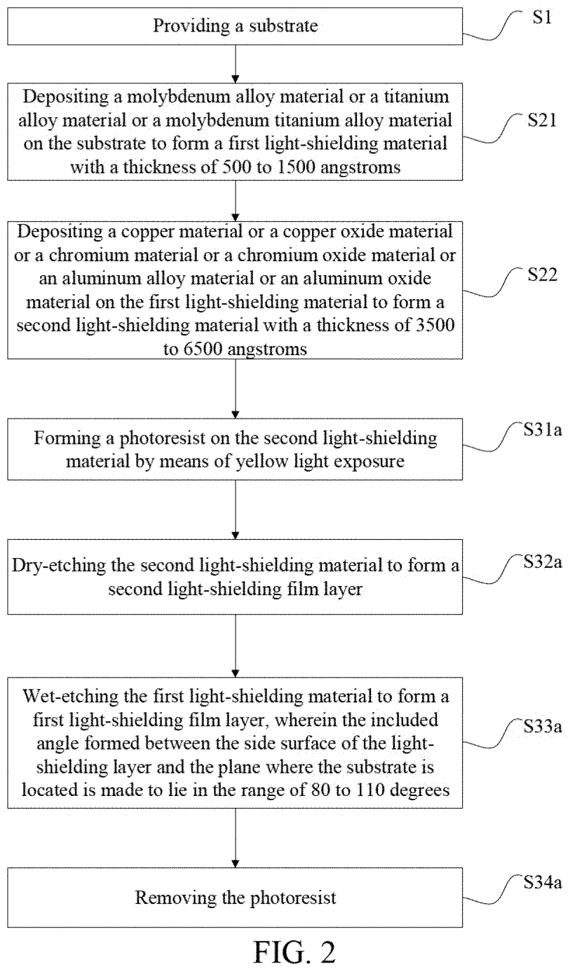

FIG. 2 is a flowchart of a second embodiment of the method for manufacturing an array substrate of the present application. As shown in FIG. 2, the main difference between this embodiment and the first embodiment are:

the step S2 of depositing the light-shielding material on the substrate includes:

S21: depositing a molybdenum alloy material or a titanium alloy material or a molybdenum titanium alloy material on the substrate to form a first light-shielding material with a thickness of 500 to 1500 angstroms; and

S22: depositing a copper material or a copper oxide material or a chromium material or a chromium oxide material or an aluminum alloy material or an aluminum oxide material on the first light-shielding material to form a second light-shielding material with a thickness of 3500 to 6500 angstroms. It adopts a double-layer film structure, for example, the bottom part is made of molybdenum alloy etc., which can improve the adhesion and so on.

The first light-shielding film layer and the second light-shielding film layer use different etching methods, and a more suitable etching gas or etching solution can be selected according to the material of each film layer, so that the side surface of the light-shielding layer 20 can be etched more vertically. Optionally, The step S3 of etching the light-shielding material to form a light-shielding layer 20, and the included angle between the side surface of the light-shielding layer 20 and the plane where the substrate is located is 80 to 110 degrees includes:

S31a: forming a photoresist on the second light-shielding material by means of yellow light exposure;

S32a: dry-etching the second light-shielding material to form the second light-shielding film layer;

S33a: wet-etching the first light-shielding material to form a second light-shielding film layer, where the included angle between the side surface of the light-shielding layer 20 and the plane where the substrate is located is 80 to 110 degrees; and

S34a: removing the photoresist;

In this embodiment, if dry etching is used for the second light-shielding film layer, the etching is more sufficient and uniform, which is beneficial to make the side of the second light-shielding film layer more vertical. The second light-shielding film layer adopts wet etching, which on the one hand can improve the etching efficiency and production efficiency, on the other hand, the two film layers can be etched with more targeted etching gases or etching solutions, so as to reduce the problem of uneven edges caused by different etching efficiencies caused by different materials of the two film layers when a general etching solution is used. It is beneficial to make the side surfaces of the entire light-shielding layer composed of the second light-shielding film layer and the second light-shielding film layer more vertical.

In particular, FIG. 9a shows a schematic diagram of a light-shielding layer 20 of a double-layer film structure according to an embodiment of the present disclosure. In this embodiment, the second light-shielding layer 202 is disposed on the first light-shielding layer 201, and the first light-shielding layer 201 is slightly longer than the second light-shielding layer 202 so that each end of the underlying first light-shielding layer 201 exceeds the corresponding end of the second light-shielding layer 202. However, both the side surface of the underlying first light-shielding layer 201 and the corresponding side surface of the second light-shielding layer 202 at the same end are substantially vertical so that the light emitted by the panel will not be reflected back into the substrate by the side of the light-shielding layer 20, which is beneficial to improve the transmittance of the light, improve the brightness of the display panel, and reduce power consumption. In this case, it can prevent the light reflected back into the substrate from hitting the semiconductor layer of the thin film transistor 301 and other positions, which will adversely affect the properties of the element.

Alternatively. FIG. 9b is a schematic diagram of a light-shielding layer 20 of a double-layer film structure according to another embodiment of the present disclosure. In this embodiment, the second light-shielding layer 202 is disposed on the first light-shielding layer 201, and the first light-shielding layer 201 is slightly shorter than the second light-shielding layer 202 so that each end of the second light-shielding layer 202 exceeds the corresponding end of the underlying first light-shielding layer 201. However, both the side surface of the underlying first light-shielding layer 201 and the corresponding side surface of the second light-shielding layer 202 at the same end are substantially vertical so that the light emitted by the panel will not be reflected back into the substrate by the side of the light-shielding layer 20, which is beneficial to improve the transmittance of the light, improve the brightness of the display panel, and reduce power consumption. In this case, it can prevent the light reflected back into the substrate from hitting the semiconductor layer of the thin film transistor 301 and other positions, which will adversely affect the properties of the element.

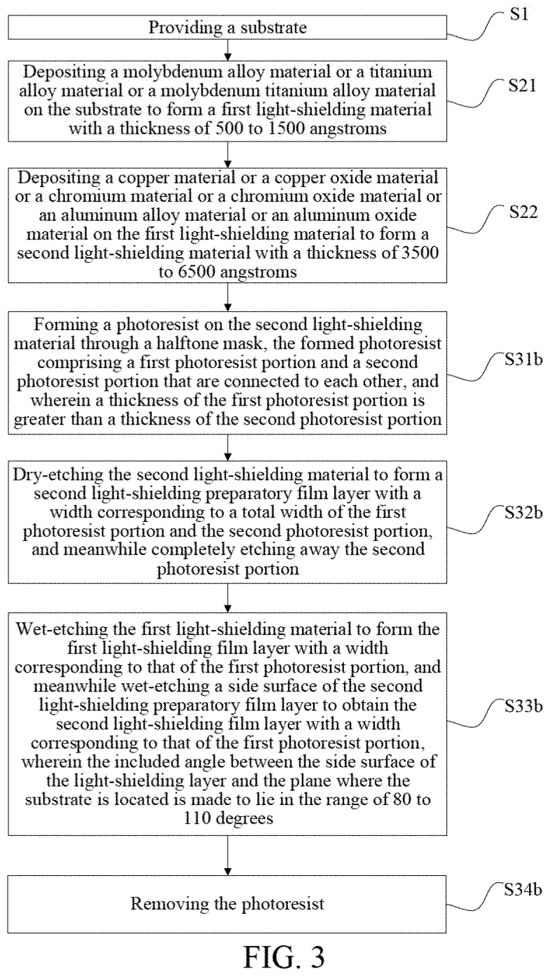

FIG. 3 is a flowchart of a third embodiment of the method for manufacturing an array substrate of the present application. As shown in FIG. 3, the main difference between this embodiment and the second embodiment are:

the step S3 of etching the light-shielding material to form a light-shielding layer 20, where the angle between the side surface of the formed light-shielding layer and the plane where the substrate is located is 80 to 110 degrees includes:

S31b: forming a photoresist on the second light-shielding material through a halftone mask, the formed photoresist including a first photoresist portion and a second photoresist portion that are connected to each other, and the second photoresist portion is arranged in a circle around the periphery of the first photoresist portion, where the thickness of the first photoresist portion is greater than the thickness of the second photoresist portion:

S32b: dry-etching the second light-shielding material to form a second light-shielding preparatory film layer with a width corresponding to the total width of the first photoresist portion and the second photoresist portion, and at the same time, completely etching the second photoresist portion;

S33b: wet-etching the first light-shielding material to form a second light-shielding film layer with a width corresponding to the first photoresist portion, and at the same time, wet-etching the side surface of the second light-shielding preparatory film layer to obtain a second light-shielding film layer with a width corresponding to the first photoresist portion, and the angle between the side surface of the light-shielding layer 20 and the plane where the substrate is located is 80 to 110 degrees; and

S34b removing the photoresist;

The first photoresist portion is located in the middle, and the second photoresist portion is arranged around the periphery of the first photoresist portion, that is, the second photoresist portion is located at the periphery of the photoresist, and is slightly wider than the width of the second light-shielding film layer and the second light-shielding film layer to be formed. In this case, the second light-shielding film layer below is formed by etching, and the width reserved on the side of the above second light-shielding layer preparatory film can be etched away again in this etching to avoid the final formed second light-shielding film layer being smaller than the designed width. Moreover, at this time, the second light-shielding preparatory film layer is etched from the side. Compared with the case of etching from the upper surface, the second light-shielding film layer formed by etching will be more uniform and vertical, which can well reflect the light irradiated on the side of the light-shielding layer 20 to the light-emitting surface and improve the transmittance.

In addition, in the related art, the reason why the side surface of the light-shielding layer 20 is inclined is that in addition to the fact that the upper surface edge of the film layer is easier to be etched, the lower edge of the film layer usually has a certain tailing, which not only causes the side surface to be inclined, but also causes the formed light-shielding layer to be slightly wider than the designed width, resulting in a further reduction of the light transmittance. This embodiment can avoid such a tailing problem and further improve the transmittance.

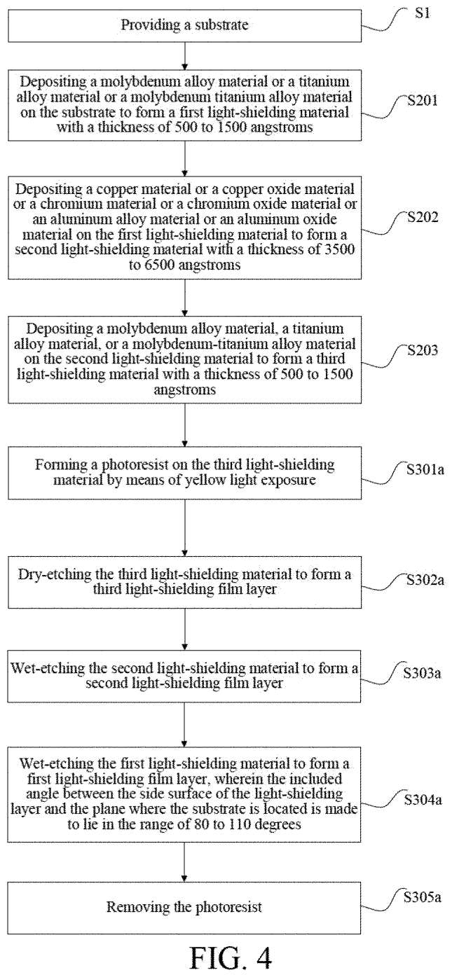

FIG. 4 is a flowchart of a fourth embodiment of the method for manufacturing an array substrate of the present application. As shown in FIG. 4, the main difference between this embodiment and the second embodiment are:

the step S2 of depositing the light-shielding material on the substrate includes:

S201: depositing a molybdenum alloy material or a titanium alloy material or a molybdenum titanium alloy material on the substrate to form a first light-shielding material with a thickness of 500 to 1500 angstroms:

S202: depositing a copper material or a copper oxide material or a chromium material or a chromium oxide material or an aluminum alloy material or an aluminum oxide material on the first light-shielding material to form a second light-shielding material with a thickness of 3500 to 6500 angstroms; and

S203: depositing a molybdenum alloy material, a titanium alloy material, or a molybdenum-titanium alloy material on the second light-shielding material to form a third light-shielding material with a thickness of 500 to 1500 angstroms. The light-shielding layer 20 adopts a three-layer film structure, and the upper and lower film layers are made of molybdenum alloy and other materials, which can improve the adhesion; at the same time, it is beneficial to use different etching methods for different film layers.

Correspondingly, the step S3 of etching the light-shielding material to form a light-shielding layer 20, where the angle between the side surface of the formed light-shielding layer and the plane where the substrate is located is 80 to 110 degrees includes:

S301a: forming a photoresist by exposing to yellow light above the third light-shielding material;

S302a: dry-etching the third light-shielding material to form the third light-shielding film;

S303a: wet-etching the second light-shielding material to form the second light-shielding film layer;

S304a: wet-etching the first light-shielding material to form a second light-shielding film layer, where the included angle between the side surface of the light-shielding layer 20 and the plane where the substrate is located is 80 to 110 degrees; and

S305a: removing the photoresist;

In this embodiment, the third light-shielding film is formed by dry etching, so that the third light-shielding film can be etched more uniformly and vertically; and the second light-shielding film layer and the second light-shielding film layer are formed by wet etching, which can improve the Etching efficiency. The etching solutions used in step S303a and step S304a are typically different, and typically only has an etching effect on the current film layer, which is conducive to etching to obtain a more vertical side; of course, it is also possible to use a general etching solution, which is conducive to save production time. Of course, it is also possible to use dry etching to etch the first light-shielding material.

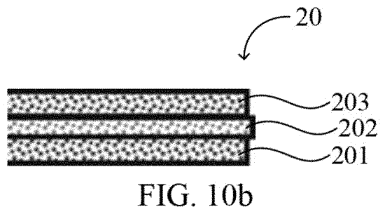

In particular, FIG. 10a shows a schematic diagram of a light-shielding layer 20 of a three-layer film structure according to an embodiment of the present disclosure. In this embodiment, the second light-shielding layer 202 is disposed on the first light-shielding layer 201, and the third light-shielding layer 203 is disposed on the second light-shielding layer 202. Furthermore, the first light-shielding layer 201 and the third light-shielding layer 203 are aligned or in other word flush with each other at each of both ends, and the corresponding end of the second light-shielding layer 202 that is sandwiched between the first light-shielding layer 201 and the third light-shielding layer 203 is retracted from the corresponding ends of the first and third light-shielding layer 203s. That is, the length of the second light-shielding layer 202 is in fact slightly shorter than that of the first light-shielding layer 201 and the third light-shielding layer 203, while the first light-shielding layer 201 and the third light-shielding layer 203 have substantially equal length. Nevertheless, the side surface of the underlying first light-shielding layer 201, the corresponding side surface of the second light-shielding layer 202, and the corresponding side surface of the third light-shielding layer 203 at each same end are substantially vertical so that the light emitted by the panel will not be reflected back into the substrate by the side of the light-shielding layer 20, which is beneficial to improve the transmittance of the light, improve the brightness of the display panel, and reduce power consumption. In this case, it can prevent the light reflected back into the substrate from hitting the semiconductor layer of the thin film transistor 301 and other positions, which will adversely affect the properties of the element.

Alternatively, FIG. 10b shows a schematic diagram of a light-shielding layer 20 of a three-layer film structure according to another embodiment of the present disclosure. In this embodiment, the second light-shielding layer 202 is disposed on the first light-shielding layer 201, and the third light-shielding layer 203 is disposed on the second light-shielding layer 202. Furthermore, the first light-shielding layer 201 and the third light-shielding layer 203 are aligned or in other word flush with each other at each of both ends, and the corresponding end of the second light-shielding layer 202 that is sandwiched between the first light-shielding layer 201 and the third light-shielding layer 203 protrudes from the corresponding ends of the first and third light-shielding layer 203s. That is, the length of the second light-shielding layer 202 is in fact slightly greater than that of the first light-shielding layer 201 and the third light-shielding layer 203, while the first light-shielding layer 201 and the third light-shielding layer 203 have substantially equal length. Nevertheless, the side surface of the underlying first light-shielding layer 201, the corresponding side surface of the second light-shielding layer 202, and the corresponding side surface of the third light-shielding layer 203 at each same end are substantially vertical so that the light emitted by the panel will not be reflected back into the substrate by the side of the light-shielding layer 20, which is beneficial to improve the transmittance of the light, improve the brightness of the display panel, and reduce power consumption. In this case, it can prevent the light reflected back into the substrate from hitting the semiconductor layer of the thin film transistor 301 and other positions, which will adversely affect the properties of the element.

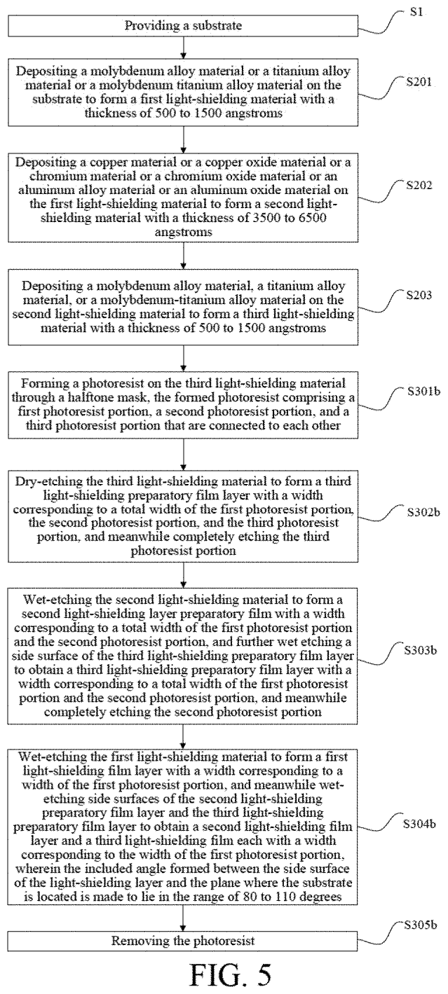

FIG. 5 is a flowchart of the fifth embodiment of the method of manufacturing the array substrate of the present application. As shown in FIG. 5, the main difference between this embodiment and the fourth embodiment is that: optionally, the step of etching the light-shielding material to form a light-shielding layer 20, where the angle between the side surface of the formed light-shielding layer and the plane where the substrate is located is 80 to 110 degrees includes:

S301b: forming a photoresist through a halftone mask on the third light-shielding material, the formed photoresist includes a first photoresist portion, a second photoresist portion and a third photoresist portion that are connected to each other, where the second photoresist portion is arranged in a circle around the periphery of the first photoresist portion, the third photoresist portion is arranged in a circle around the periphery of the second photoresist portion, where the thicknesses of the first photoresist portion, the second photoresist portion and the third photoresist portion are sequentially reduced;

S302b: dry etching the third light-shielding material to form a third light-shielding preparatory film layer with a width corresponding to the total width of the first photoresist portion, the second photoresist portion and the third photoresist portion, and at the same time, completely etching the third photoresist portion;

S303b: wet-etching the second light-shielding material to form a second light-shielding layer preparatory film with a width corresponding to the total width of the first photoresist portion and the second photoresist portion, and at the same time, wet-etching the side surface of the third light-shielding preparatory film layer to obtain a third light-shielding preparatory film layer with a width corresponding to the total width of the first photoresist portion and the second photoresist portion, and at the same time, fully etching the second photoresist portion;

S304b: wet-etching the first light-shielding material to form a second light-shielding film layer with a width corresponding to the width of the first photoresist portion, and at the same time, wet-etching the side surfaces of the second light-shielding preparatory film layer and the third light-shielding preparatory film layer to obtain a second light-shielding film layer and a third light-shielding film with a width corresponding to the width of the first photoresist portion layer, where the angle between the side surface of the light-shielding layer 20 and the plane where the substrate is located is 80 to 110 degrees; and

S305b: removing the photoresist:

The second photoresist portion is arranged in a circle around the periphery of the first photoresist portion, and the third photoresist portion is arranged in a circle around the periphery of the second photoresist portion. Similarly, in this embodiment, before etching the second light-shielding film layer, the sides of the second light-shielding film layer and the third light-shielding film have reserved a certain width. In that case, in the final product, it is not easy for the upper layer to be shorter than the lower layer due to over-etching, so that the overall side surface of the three-layer is more vertical.

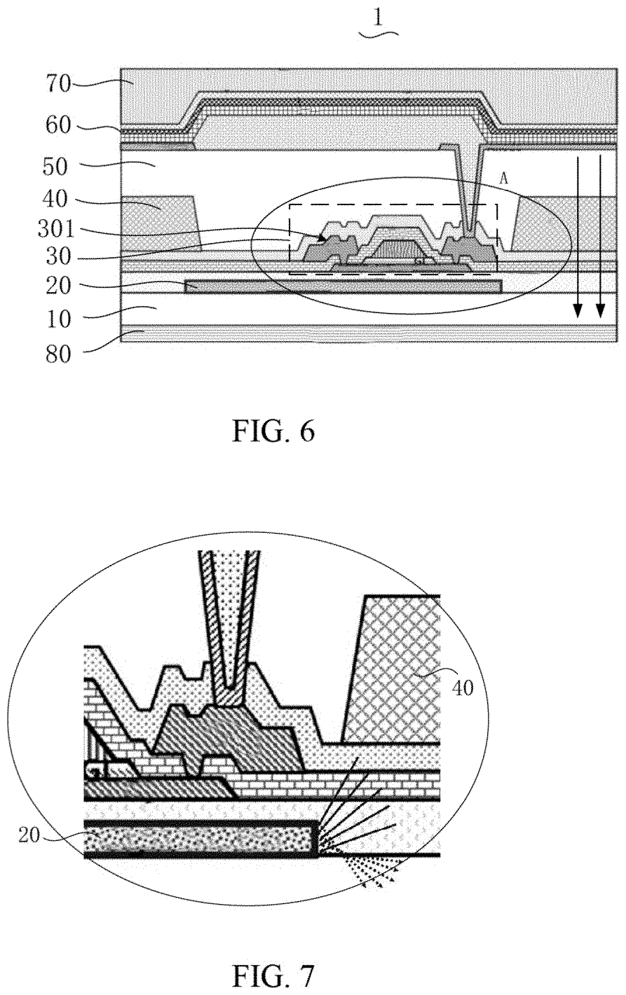

The application also discloses an array substrate 1. As shown in the lower part of FIG. 6, with reference to FIGS. 1 to 5, the array substrate disclosed in the present application is prepared by using any one of the methods for fabricating an array substrate disclosed in the present application, and includes a substrate 10, a light-shielding layer 20, and a thin film transistor layer 30. The light-shielding layer 20 is located on the substrate 10. The thin film transistor layer 30 is located on the light-shielding layer 20. The angle between the side surface of the light-shielding layer 20 and the plane of the substrate 10 is 80 degrees to 110 degrees.

The present application further discloses a display panel. As shown in FIG. 6, the display panel includes a light-emitting structure 60, an encapsulation layer 70, and the above-mentioned array substrate 1. The array substrate 1 includes a color filter layer 40 and a planarization layer 50. The thin film transistor layer 30 includes a thin film transistor 301. The color filter layer 40 is disposed on the side of the thin film transistor 30. The planarization layer 40 is disposed on the light-shielding layer 20 and the thin film transistor layer 30. The light emitting structure 60 is formed on the planarization layer 40. The encapsulation layer 70 is disposed on the light emitting structure 60. The angle between the side surface of the light-shielding layer 20 and the plane of the substrate 10 is 80 degrees to 110 degrees. In addition, a polarizer 80 is further provided on an outer side of the substrate 10.

The light-emitting structure 60 further includes structures such as a cathode, an anode, and an active light-emitting layer, but this part is not the focus of this application and will not be detailed.

Optionally, the light-shielding layer 20 includes a first light-shielding film layer and a second light-shielding film layer. The first light-shielding film layer is formed on the substrate. The second light-shielding film layer is formed on the first light-shielding film layer. The angle between the side surface of the light-shielding layer 20 composed of the second light-shielding film layer and the second light-shielding film layer and the plane where the substrate 10 is located lies in the range of 85 degrees to 95 degrees. The second light-shielding film layer can be protruded or retracted relative to the second light-shielding film layer, but the length difference needs to be greater than or equal to 0 and less than or equal to 1.5 times the thickness of the second light-shielding film layer.

Or the light-shielding layer 20 includes a first light-shielding film layer, a second light-shielding film layer and a third light-shielding film layer. The first light-shielding film layer is formed on the substrate, the second light-shielding film layer is formed on the first light-shielding film layer, and the third light-shielding film layer is formed on the second light-shielding film layer. The angle between the side surface of the light-shielding layer 20 composed of the second light-shielding film layer, the second light-shielding film layer and the third light-shielding film layer and the plane where the substrate 10 is located is 85 degrees to 95 degrees. The first light-shielding film layer and the third light-shielding film layer are flush, and the second light-shielding film layer can be relatively convex or retracted as illustrated in FIGS. 10a and 10b as already discussed above, but the length difference needs to be greater than or equal to 0, and less than or equal to 1.5 times the thickness of the second light-shielding film layer.

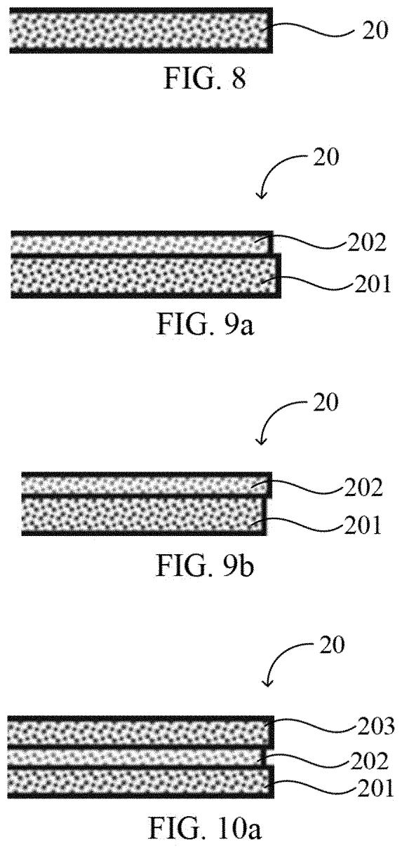

FIG. 7 is a partial enlarged view of area A in FIG. 6 of the present application. As shown in FIG. 7, the light emitted by the light emitting structure 60, especially when in the film layer (such as the color filter layer) in the panel, is deflected at a certain angle due to the difference in refractive indices, so that it is irradiated on the side surface of the light-shielding layer 20. If in the related art, the inclined side surface (that is, the angle between the side surface of the light-shielding layer 20 and the substrate is greater than 110 degrees), the light will be reflected back to the color filter layer 40 or the thin film transistor layer 30, which may cause adverse effects and affect the display effect. In the present application, as shown in FIG. 7, the light can be reflected to the light-emitting surface, which can not only improve the adverse effects, but also improve the transmittance of light.

Of course, in addition to the array substrate 1 shown in FIG. 6, the array substrate 1 may also not be provided with film layers such as a light-emitting structure and an encapsulation layer, but be formed on another substrate, that is, the display panel further includes an opposite substrate. The opposite substrate is provided with a light-emitting structure and an encapsulation layer, and then the opposite substrate and the array substrate are aligned and bonded together to form a cell.

The various technical features of the above embodiments can be combined arbitrarily. For the sake of brevity, the present application will not attempt to enumerate all possible combinations of the technical features in the above embodiments. However, as long as there is no contradiction in the combination of these technical features, such a combination should be considered to be falling in the scope described in this specification.

The foregoing is a further detailed description of the present application in conjunction with specific optional embodiments, but it should not be construed as that the specific implementation of the present application will be limited to these descriptions. For those having ordinary skill in the technical field of the present application, without departing from the scope and spirit of the present application, some simple deductions or substitutions can be made, which should all be regarded as falling in the scope of protection of the present application.

What is claimed is:

1. A method of manufacturing an array substrate, comprising:
providing a substrate;
depositing a light-shielding material on the substrate; and
etching the light-shielding material to form a light-shielding layer, wherein an included angle formed between a side surface of the formed light-shielding layer and a plane where the substrate is located lies in the range of 80 to 110 degrees.

2. The method of claim 1, wherein the operation of depositing the light-shielding material on the substrate comprises:
depositing a molybdenum alloy material or a titanium alloy material or a molybdenum titanium alloy material on the substrate to form a first light-shielding material with a thickness of 500 to 1500 angstroms; and
depositing a copper material or a copper oxide material or a chromium material or a chromium oxide material or an aluminum alloy material or an aluminum oxide material on the first light-shielding material to form a second light-shielding material with a thickness of 3500 to 6500 angstroms.

3. The method of claim 2, wherein the operation of etching the light-shielding material to form the light-shielding layer wherein the included angle formed between the side surface of the formed light-shielding layer and the plane where the substrate is located lies in the range of 80 to 110 degrees comprises:
forming a photoresist on the second light-shielding material by means of yellow light exposure;
dry-etching the second light-shielding material to form a second light-shielding film layer;
wet-etching the first light-shielding material to form a first light-shielding film layer, wherein the included angle formed between the side surface of the light-shielding layer and the plane where the substrate is located is made to lie in the range of 80 to 110 degrees; and
removing the photoresist.

4. The method of claim 2, wherein the operation of etching the light-shielding material to form the light-shielding layer wherein the included angle formed between the side surface of the formed light-shielding layer and the plane wherein the substrate is located lies in the range of 80 to 110 degrees comprises:
forming a photoresist on the second light-shielding material through a halftone mask, the formed photoresist comprising a first photoresist portion and a second photoresist portion that are connected to each other, and wherein the second photoresist portion is arranged in a circle around a periphery of the first photoresist portion, and wherein a thickness of the first photoresist portion is greater than a thickness of the second photoresist portion;
dry-etching the second light-shielding material to form a second light-shielding preparatory film layer with a width corresponding to a total width of the first photoresist portion and the second photoresist portion, and meanwhile completely etching away the second photoresist portion;
wet-etching the first light-shielding material to form the first light-shielding film layer with a width corresponding to that of the first photoresist portion, and further wet-etching a side surface of the second light-shielding preparatory film layer to obtain the second light-shielding film layer with a width corresponding to that of the first photoresist portion, wherein the included angle between the side surface of the light-shielding layer and the plane where the substrate is located is made to lie in the range of 80 to 110 degrees; and
removing the photoresist.

5. The method of claim 1, wherein the operation of depositing the light-shielding material on the substrate comprises:
depositing a molybdenum alloy material or a titanium alloy material or a molybdenum-titanium alloy material on the substrate to form a first light-shielding material with a thickness of 500 to 1500 angstroms;
depositing a copper material or a copper oxide material or a chromium material or a chromium oxide material or an aluminum alloy material or an aluminum oxide material on the first light-shielding material to form a second light-shielding material with a thickness of 3500 to 6500 angstroms; and
depositing a molybdenum alloy material, a titanium alloy material, or a molybdenum-titanium alloy material on the second light-shielding material to form a third light-shielding material with a thickness of 500 to 1500 angstroms.

6. The method of claim 5, wherein the operation of etching the light-shielding material to form the light-shielding layer wherein the included angle formed between the side surface of the formed light-shielding layer and the plane where the substrate is located lies in the range of 80 to 110 degrees comprises:
forming a photoresist on the third light-shielding material by means of yellow light exposure;
dry-etching the third light-shielding material to form a third light-shielding film layer;
wet-etching the second light-shielding material to form a second light-shielding film layer;
wet-etching the first light-shielding material to form a first light-shielding film layer, wherein the included angle between the side surface of the light-shielding layer and the plane where the substrate is located is made to lie in the range of 80 to 110 degrees; and
removing the photoresist.

7. The method of claim 5, wherein the operation of etching the light-shielding material to form the light-shielding layer wherein the included angle formed between the side surface of the formed light-shielding layer and the plane where the substrate is located lies in the range of 80 to 110 degrees comprises:
forming a photoresist on the third light-shielding material through a halftone mask, the formed photoresist comprising a first photoresist portion, a second photoresist portion, and a third photoresist portion that are connected to each other, wherein the second photoresist portion is arranged in a circle around a periphery of the first photoresist portion, and the third photoresist portion is arranged in a circle around a periphery of the second photoresist portion, wherein thicknesses of the first photoresist portion, the second photoresist portion, and the third photoresist portion are sequentially reduced;
dry-etching the third light-shielding material to form a third light-shielding preparatory film layer with a width corresponding to a total width of the first photoresist portion, the second photoresist portion, and the third photoresist portion, and meanwhile completely etching the third photoresist portion;
wet-etching the second light-shielding material to form a second light-shielding layer preparatory film with a width corresponding to a total width of the first photoresist portion and the second photoresist portion, and further wet-etching a side surface of the third light-shielding preparatory film layer to obtain a third light-shielding preparatory film layer with a width corresponding to a total width of the first photoresist portion and the second photoresist portion, and meanwhile completely etching the second photoresist portion;
wet-etching the first light-shielding material to form a first light-shielding film layer with a width corresponding to a width of the first photoresist portion, and wet-etching side surfaces of the second light-shielding preparatory film layer and the third light-shielding preparatory film layer to obtain a second light-shielding film layer and a third light-shielding film each with a width corresponding to the width of the first photoresist portion, wherein the included angle formed between the side surface of the light-shielding layer and the plane where the substrate is located is made to lie in the range of 80 to 110 degrees; and
removing the photoresist.

8. An array substrate, comprising a substrate, a light-shielding layer, and a thin film transistor layer: wherein the light-shielding layer is disposed on the substrate, and the thin film transistor layer is disposed on the light-shielding layer, wherein an included angle formed between a side surface of the light-shielding layer and a plane where the substrate is located lies in the range of 80 degrees to 110 degrees.

9. The array substrate of claim 8, wherein the light-shielding layer comprises a first light-shielding film layer and a second light-shielding film layer, wherein the first light-shielding film layer is formed on the substrate, and the second light-shielding film layer is formed on the first light-shielding film layer.

10. The array substrate of claim 9, wherein a thickness of the second light-shielding film layer lies in the range of 500 to 1500 angstroms, and the second light-shielding film layer is formed depositing a molybdenum alloy material or a titanium alloy material or a molybdenum titanium alloy material on the substrate;
wherein a thickness of the second light-shielding film layer lies in the range of 3500 to 6500 angstroms, and the second light-shielding film layer is formed by depositing a copper material or a copper oxide material or a chromium material or a chromium oxide material or an aluminum alloy material or an aluminum oxide material on the first light-shielding layer.

11. The array substrate of claim 10, wherein the second light-shielding film layer is formed by dry etching, and the second light-shielding film layer is formed by wet etching.

12. The array substrate of claim 8, wherein the light-shielding layer comprises a first light-shielding film layer, a second light-shielding film layer, and a third light-shielding film layer; wherein the first light-shielding film layer is formed on the substrate, the second light-shielding film layer is formed on the first light-shielding film layer, and the third light-shielding film layer is formed on the second light-shielding film layer.

13. The array substrate of claim 12, wherein a thickness of the second light-shielding film layer lies in the range of 500 to 1500 angstroms, and the second light-shielding film layer is formed by depositing a molybdenum alloy material or a titanium alloy material or a molybdenum titanium alloy material on the substrate;
wherein a thickness of the second light-shielding film layer lies in the range of 3500 to 6500 angstroms, and the second light-shielding film layer is formed by depositing a copper material or a copper oxide material or a chromium material or a chromium oxide material or an aluminum alloy material or an aluminum oxide material on the first light-shielding layer;
wherein a thickness of the third light-shielding film layer lies in the range of 500 to 1500 angstroms, and the third light-shielding film layer is formed by depositing a molybdenum alloy material, a titanium alloy material, or a molybdenum-titanium alloy material on the second light-shielding layer.

14. The array substrate of claim 13, wherein the second light-shielding film layer is formed by dry etching, the second light-shielding film layer is formed by dry etching, and the third light-shielding film is formed by wet etching.

15. A display panel, comprising a light-emitting structure, an encapsulation layer, and an array substrate; wherein the array substrate comprises a color filter layer and a planarization layer; wherein the thin film transistor layer comprises a thin film transistor, the color filter layer is disposed on a side of the thin film transistor, the planarization layer is disposed on the light-shielding layer and the thin film transistor layer, the light emitting structure is disposed on the planarization layer, and the encapsulation layer is disposed on the light emitting structure;
wherein the array substrate comprises a substrate, a light-shielding layer, and a thin film transistor layer; wherein the light-shielding layer is disposed on the substrate, and the thin film transistor layer is disposed on the light-shielding layer, wherein an included angle between a side surface of the light-shielding layer and a plane where the substrate is located lies in the range of 80 degrees to 110 degrees.

16. The display panel of claim 15, wherein the light-shielding layer comprises a first light-shielding film layer, a second light-shielding film layer, and a third light-shielding film layer; wherein the first light-shielding film layer is formed on the substrate, the second light-shielding film layer is formed on the first light-shielding film layer, and the third light-shielding film layer is formed on the second light-shielding film layer.

17. The display panel of claim 16, wherein a thickness of the first light-shielding film layer lies in the range of 500 to 1500 angstroms, and the first light-shielding film layer is formed by depositing a molybdenum alloy material or a titanium alloy material or a molybdenum titanium alloy material on the substrate;
wherein a thickness of the second light-shielding film layer lie in the range of 3500 to 6500 angstroms, and the second light-shielding film layer is formed by depositing a copper material or a copper oxide material or a chromium material or a chromium oxide material or an aluminum alloy material or an aluminum oxide material on the first light-shielding layer;
wherein a thickness of the third light-shielding film layer lies in the range of 500 to 1500 angstroms, and the third light-shielding film layer is formed by depositing a molybdenum alloy material, a titanium alloy material, or a molybdenum-titanium alloy material on the second light-shielding layer.

18. The display panel of claim 17, wherein the first light-shielding film layer is formed by dry etching, the second light-shielding film layer is formed by dry etching, and the third light-shielding film is formed by wet etching.

19. The display panel of claim 16, wherein the light-shielding layer comprises a first light-shielding film layer and a second light-shielding film layer, wherein the first light-shielding film layer is formed on the substrate, and the second light-shielding film layer is formed on the first light-shielding film layer;
wherein a thickness of the first light-shielding film layer lies in the range of 500 to 1500 angstroms, and the first light-shielding film layer is formed by depositing a molybdenum alloy material or a titanium alloy material or a molybdenum titanium alloy material on the substrate;
wherein a thickness of the second light-shielding film layer lies in the range of 3500 to 6500 angstroms, and the second light-shielding film layer is formed by depositing a copper material or a copper oxide material or a chromium material or a chromium oxide material or an aluminum alloy material or an aluminum oxide material on the first light-shielding layer;
wherein a thickness of the third light-shielding film layer is 3500 to 6500 angstroms, and the third light-shielding film layer is formed by depositing a copper material or a copper oxide material or a chromium material or a chromium oxide material or an aluminum alloy material or an aluminum oxide material on the second light-shielding layer.

20. The display panel of claim 19, wherein the first light-shielding film layer is formed by dry etching, and the second light-shielding film layer is formed by wet etching.
